(19) United States
(12) Patent Application Publication
(10) Pub. No.: US 2023/0221147 A1
(43) Pub. Date: Jul. 13, 2023

(54) ROTATION ANGLE DETECTOR

(71) Applicant: NIDEC COPAL CORPORATION, Tokyo (JP)

(72) Inventor: Kiyoyasu SAITO, Tokyo (JP)

(21) Appl. No.: 18/149,670

(22) Filed: Jan. 4, 2023

(30) Foreign Application Priority Data
Jan. 7, 2022 (JP) 2022-001703

(51) Int. Cl. G01D 5/14; G01B 7/30; H10N 50/10

(52) U.S. Cl. CPC G01D 5/145; G01B 7/30; H10N 50/10

(57) ABSTRACT

A rotation angle detector is smaller and less expensive and can improve detection accuracy. The rotation angle detector includes a ring magnet rotatable together with a hollow shaft and including magnetized sections having different poles and being alternately arranged in a direction of rotation of the hollow shaft, and a magnetoresistive sensor that detects a magnetic flux of the magnetized sections. The magnetized sections include an origin-indicator magnetized section that generates a magnetic flux indicating completion of one rotation of the hollow shaft. A controller electrically connected to the rotation angle detector can detect both the rotation angle of the hollow shaft and the origin using the single ring magnet and the single MR sensor. The rotation angle detector is thus smaller and less expensive and can improve detection accuracy.

### RELATED APPLICATIONS

The present application claims priority to Japanese Application Number 2022-001703, filed Jan. 7, 2022, the disclosure of which is hereby incorporated by reference herein in its entirety.

### BACKGROUND

### Technical Field

The present invention relates to a rotation angle detector for detecting the rotation angle of a rotator.

### Description of the Background

For example, Patent Literature 1 describes a position detection sensor including a rotational shaft to which a detection target rotator is connected. A first rotor and a second rotor are fixed on the rotational shaft. The first rotor includes numerous pairs of different poles arranged alternately in the circumferential direction. The second rotor includes a single pair of different poles arranged in the circumferential direction. A housing for these rotors also accommodates a first sensor facing the first rotor from radially outside and a second sensor facing the second rotor from radially outside.

The numerous pairs of different poles in the first rotor cause the first sensor to output a sinusoidal output signal, which is used to detect the position (angle of rotation) of the detection target rotator. The single pair of different poles in the second rotor cause the second sensor to output a square wave output signal, which is used to detect the number of rotations performed by the detection target rotator (origin).

### CITATION LIST

### Patent Literature

Patent Literature 1: Japanese Unexamined Patent Application Publication No. 10-311742

### BRIEF SUMMARY

However, the position detection sensor described in Patent Literature 1 includes the pair of rotors fixed coaxially on the rotational shaft and the pair of sensors accommodated in the housing for the respective rotors. The position detection sensor including many parts can be large and increase the manufacturing cost. The rotational shaft can also have a large moment of inertia. In particular, the detection target rotator with a small mass can lower the accuracy of position detection.

One or more aspects of the present invention are directed to a rotation angle detector that is smaller and less expensive and can improve detection accuracy.

A rotation angle detector according to one aspect of the present invention is a rotation angle detector for detecting a rotation angle of a rotator. The rotation angle detector includes a magnet rotatable together with the rotator and including a plurality of magnetized sections having different poles and being alternately arranged in a direction of rotation of the rotator, and a magnetic sensor that detects a magnetic flux of the plurality of magnetized sections. The plurality of magnetized sections include an origin-indicator magnetized section that generates a magnetic flux indicating completion of one rotation of the rotator.

The rotation angle detector according to the above aspect of the present invention is smaller and less expensive and can improve detection accuracy.

### BRIEF DESCRIPTION OF DRAWINGS

FIG. 1 is a schematic partial cross-sectional view of a rotation angle detector.

FIG. 2 is a graph of a magnetic flux detected with a 12-pole ring magnet in comparison with a magnetic flux detected with a 2-pole ring magnet.

FIG. 3 is a schematic view of a ring magnet in a first embodiment together with a graph of a magnetic flux detected with the ring magnet.

FIG. 4 is a schematic view of a ring magnet in a second embodiment together with a graph of a magnetic flux detected with the ring magnet.

FIG. 5 is a schematic view of a ring magnet in a third embodiment together with a graph of a magnetic flux detected with the ring magnet.

FIG. 6 is a schematic view of ring magnets in fourth and fifth embodiments.

FIG. 7 is a schematic view of a ring magnet in a sixth embodiment together with a graph of a magnetic flux detected with the ring magnet.

FIG. 8 is a schematic view of a ring magnet in a seventh embodiment together with a graph of a magnetic flux detected with the ring magnet.

FIG. 9 is a schematic view of a ring magnet in an eighth embodiment together with a graph of a magnetic flux detected with the ring magnet.

FIG. 10 is a schematic view of ring magnets in ninth and tenth embodiments.

FIG. 11 is a schematic view of a rotation angle detector according to an eleventh embodiment together with a graph of magnetic fluxes detected with the rotation angle detector.

### DETAILED DESCRIPTION

One or more embodiments of the present invention will now be described in detail with reference to the drawings.

### First Embodiment

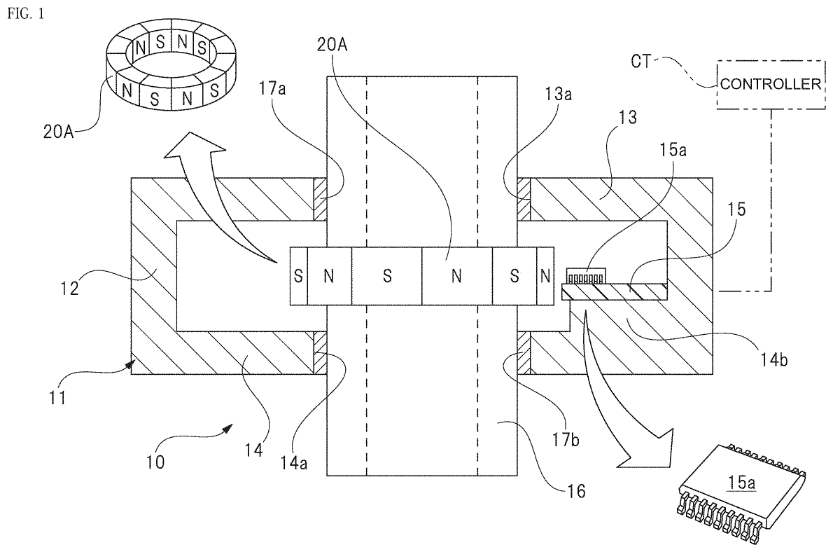

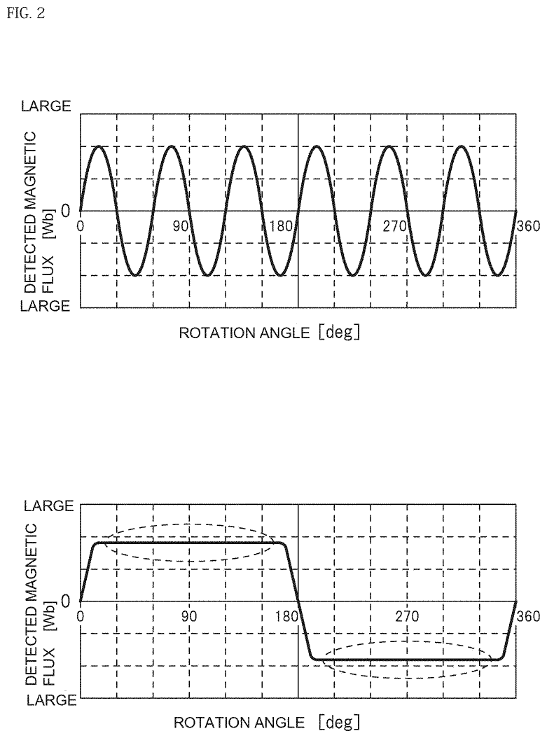

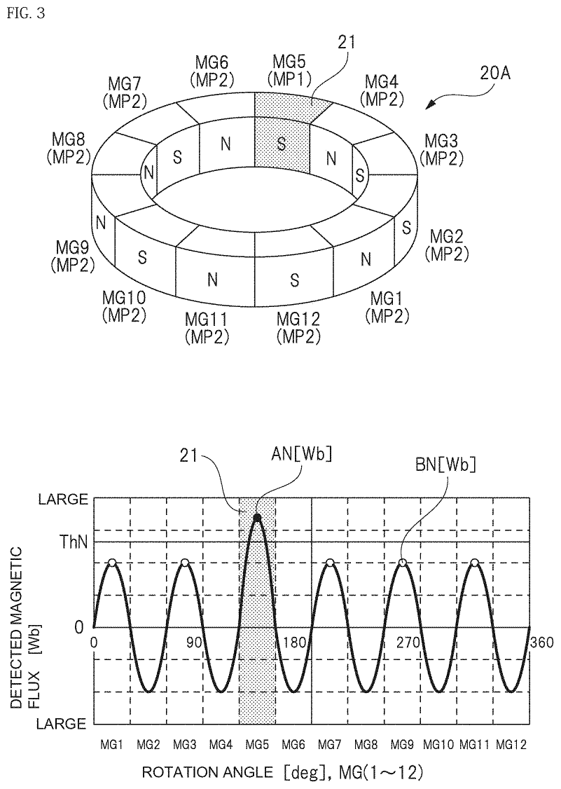

FIG. 1 is a schematic partial cross-sectional view of a rotation angle detector. FIG. 2 is a graph of a magnetic flux detected with a 12-pole ring magnet in comparison with a magnetic flux detected with a 2-pole ring magnet. FIG. 3 is a schematic view of a ring magnet in a first embodiment together with a graph of a magnetic flux detected with the ring magnet.

A rotation angle detector 10 shown in FIG. 1 is, for example, incorporated into a servomotor (not shown) for driving a joint of an industrial robot. Thus, a controller CT that is electrically connected to the rotation angle detector 10 to control the industrial robot can control a joint-drive servomotor with high precision while accurately detecting the status of rotation of the joint-drive servomotor.

The rotation angle detector 10 includes a housing 11 that is substantially annular disk with a hollow. The housing 11 includes a substantially cylindrical sidewall 12, a top plate 13 that closes the hollow at one axial end (upper end in the figure) of the sidewall 12, and a bottom plate 14 that closes the hollow at the other axial end (lower end in the figure) of the sidewall 12. Through-holes 13a and 14a extend through the center of each of the top plate 13 and the bottom plate 14 to allow a hollow shaft (rotator) 16 to be placed through the through-holes 13a and 14a.

The bottom plate 14 is integral with a substrate support 14b. The substrate support 14b is a protrusion inside the housing 11. A sensor board 15 including a magnetoresistive (MR) sensor 15a mounted on the sensor substrate 15 is fastened to the substrate support 14b with, for example, fixing screws (not shown). Thus, the MR sensor 15a is located inside the housing 11 and axially at the middle of the housing 11. The sensor board 15 is electrically connected to the controller CT with a connector (not shown). A detection signal (detected magnetic flux in Wb) from the MR sensor 15a is output to the controller CT.

The MR sensor 15a is specifically a magnetoresistive sensor that measures the magnetic flux (magnetic field) of a ring magnet 20A rotated by the hollow shaft 16.

The rotation angle detector 10 includes the hollow shaft 16 that rotates integrally with a rotational shaft in the joint-drive servomotor. The hollow shaft 16 is placed through the through-holes 13a and 14a and is rotatably supported by the top plate 13 and bottom plate 14 of the housing 11 with a pair of bearings 17a and 17b. Thus, the housing 11 supports the hollow shaft 16 in a manner rotatable freely.

The hollow shaft 16 is substantially cylindrical and has a radial internal space that can accommodate electric wires (wiring) for driving, for example, another joint-drive servomotor. The bearings 17a and 17b are metal sliding bearings that are also referred to as plain metal bearings. Thus, the hollow shaft 16 can rotate smoothly relative to the housing 11.

The rotation angle detector 10 includes the ring magnet (magnet) 20A. The ring magnet 20A is located on the hollow shaft 16 radially outward and inside the housing 11. The ring magnet 20A is, for example, a magnet formed from a ferrite magnetic material. The ring magnet 20A is fixed to the hollow shaft 16 with an adhesive (not shown) formed from, for example, an epoxy resin, and is rotated by the rotation of the hollow shaft 16. In other words, the ring magnet 20A rotates together with the hollow shaft 16 inside the housing 11.

The ring magnet 20A, as well as the MR sensor 15a, is located axially at the middle of the housing 11. Thus, the MR sensor 15a is located radially outward from the ring magnet 20A at a predetermined clearance (air gap). The MR sensor 15a faces the ring magnet 20A. The MR sensor 15a thus detects (measures) the magnetic fluxes of multiple magnetized sections (12 poles) included in the ring magnet 20A as the hollow shaft 16 rotates.

The waveform of the detection signal (detected magnetic flux) output from the MR sensor 15a changes in accordance with the number of magnetized sections (number of poles) in the ring magnet 20A. The number of magnetized sections (number of poles) suitable for detecting the rotation angle using the MR sensor 15a will now be described.

The upper graph in FIG. 2 shows the waveform of the detection signal with the ring magnet 20A including 12 poles. The lower graph in FIG. 2 shows the waveform of the detection signal with the ring magnet 20A including two poles. The horizontal axis represents the rotation angle (deg) of the hollow shaft 16, and the vertical axis represents the magnetic flux (Wb) detected by the MR sensor 15a. A part of the detected magnetic flux waveform protruding upward from the boundary line 0 (reference) represents a magnetic flux detected with an N-polar magnetized section, and a part of the magnetic flux waveform protruding downward represents a magnetic flux detected with an S-polar magnetized section.

As shown in the upper graph in FIG. 2, with the ring magnet 20A including 12 poles, the magnetic flux detected by the MR sensor 15a is plotted as a sine wave in the shape of arcs smoothly connecting in the horizontal axis direction (representing the rotation angle). Thus, using the magnetic flux detected by the MR sensor 15a as a sinusoidal wave allows the magnetic flux detected by the MR sensor 15a to constantly vary as the rotation angle of the hollow shaft 16 changes (between 0 and 360 degrees). The controller CT can thus accurately detect the rotation angle of the hollow shaft 16 based on the detection signal from the MR sensor 15a.

As shown in the lower graph in FIG. 2, with the ring magnet 20A including two poles, the magnetic flux detected by the MR sensor 15a is plotted as a square wave. In other words, the waveform includes parts (enclosed by dashed ovals) extending straight in the horizontal axis direction (representing the rotation angle). The detected magnetic flux thus remains constant while the rotation angle of the hollow shaft 16 is in ranges from about 30 to 150 degrees and from about 210 to 330 degrees, or in other words, in ranges covering a major range of rotation angles of the hollow shaft 16. Thus, the controller CT is unable to accurately detect the rotation angle of the hollow shaft 16.

Thus, to accurately detect the rotation angle of the hollow shaft 16, the ring magnet 20A may include as many magnetized sections (poles) as appropriate (multi-polar ring magnet). In the present embodiment, the ring magnet 20A includes 12 poles as an appropriate structure.

However, as shown in the upper graph in FIG. 2, the peak values of the detected magnetic flux on the N-pole and the peak values on the S-pole are all the same magnitude both on the N- and S-poles. When such a detection signal (detected magnetic flux) is used, the controller CT detects multiple peak values with no difference and is unable to detect the origin of the hollow shaft 16 (to determine whether the hollow shaft 16 has completed one rotation).

Thus, in the present embodiment, one section (origin-indicator magnetized section) of the total of 12 magnetized sections (12 poles) generates a magnetic flux that serves as an index (mark). The controller CT can thus detect the origin of the hollow shaft 16 as well.

### Details of Ring Magnet

The structure of the ring magnet 20A in the present embodiment will now be described in detail with reference to the drawings.

As shown in FIGS. 1 and 3, the ring magnet 20A is annular and has its radially inner surface fixed to the hollow shaft 16 and its radially outer surface facing the MR sensor 15a. The ring magnet 20A includes a total of 12 magnetized sections MG1 to MG12. More specifically, the radially outer ends of the odd-numbered magnetized sections (MG1, 3, 5, 7, 9, and 11) are N-polar, and the radially outer ends of the even-numbered magnetized sections (MG2, 4, 6, 8, 10, and 12) are S-polar.

In other words, the ring magnet 20A is a ring in which the magnetized sections MG1 to MG12 of alternating polarities (N-pole and S-pole) are arranged in the direction of rotation of the hollow shaft 16. In the present embodiment, the ring magnet 20A is formed by magnetizing 12 circumferential sections in an annular magnetic material alternately to have N- and S-poles. In some embodiments, substantially tiled magnets (not shown) that are formed separately may be attached around the hollow shaft 16.

In the present embodiment, as shown in FIG. 3, the magnetized section MG5 (shaded area in the figure), of the 12 magnetized sections MG1 to MG12, serves as an origin-indicator magnetized section 21 (strongly magnetized section). In other words, the multiple magnetized sections MG1 to MG12 include the origin-indicator magnetized section 21 (magnetized section MG5), which generates a (large) magnetic flux indicating that the hollow shaft 16 has completed one rotation. More specifically, the origin-indicator magnetized section 21 has a magnetic force different from the magnetic force of each of the other magnetized sections MG1 to MG4 and MG6 to MG12, which is larger than the magnetic forces of the other magnetized sections MG1 to MG4 and MG6 to MG12. The magnetized sections MG1 to MG12, including the origin-indicator magnetized section 21 (magnetized section MG5), each have the same volume.

In this structure, the MR sensor 15a facing the ring magnet 20A outputs a sinusoidal detection signal (detected magnetic flux in Wb) as shown in the lower graph in FIG. 3. More specifically, the MR sensor 15a detects a larger magnetic flux when facing the origin-indicator magnetized section 21 (magnetized section MG5) than when facing any one of the other N-polar magnetized sections MG1, MG3, MG7, MG9, and MG11, as shown in the shaded area in the graph. In the figure, the magnetic flux level AN (Wb) detected at the black-dotted peak (marked with a black dot at one point) is about 1.5 times larger than the magnetic flux level BN (Wb) detected at the other white-dotted peaks (marked with white dots at five points) (AN≈1.5×BN). Specifically, when the magnetic flux level AN (Wb) at the point marked with a black dot represents a ripple of 100%, the magnetic flux level BN (Wb) detected at the points marked with white dots represents a ripple of about 90% (a ripple difference is about 10%).

Thus, the controller CT detecting the one outstanding peak point (marked with a black dot) can detect the completion of one rotation of the hollow shaft 16 (the origin or reference point of rotation of the hollow shaft 16). More specifically, the controller CT compares the detected magnetic flux level AN (Wb) as the major peak value (marked with a black dot) and the detected magnetic flux level BN (Wb) as the minor peak value (marked with a white dot) with a predetermined comparison threshold ThN (Wb) stored in, for example, a random-access memory (RAM) (not shown) in the controller CT (AN>ThN>BN). The controller CT thus detects the single major N-polar peak value (marked with a black dot) between 0 and 360 degrees and determines that the detected peak indicates the origin of the hollow shaft 16.

The single major peak value between 0 and 360 degrees may be an S-polar peak instead of an N-polar peak. The controller CT can detect the origin of the hollow shaft 16 as well. The magnetic forces of the magnetized sections MG1 to MG12 decrease based on thermal history. Thus, the controller CT may adjust the comparison threshold ThN based on thermal history.

### Example Method of Magnetization

To magnetize the ring magnet 20A as described above, for example, a magnetizer (not shown) is used for generating a magnetic field in the radial direction. More specifically, the magnetizer includes a total of 12 magnetic force generators corresponding to the magnetized sections MG1 to MG12 (12 poles) in the ring magnet 20A. The coil in the magnetic force generator for the magnetized section MG5 has a larger number of turns than that of the coils in the magnetic force generators for the other magnetized sections MG1 to MG4 and MG6 to MG12.

In other words, a magnetic force MP1 generated by the magnetic force generator for the magnetized section MG5 is larger than magnetic forces MP2 generated by the other magnetic force generators (MP1>MP2). The ring magnet 20A as shown in FIG. 3 may thus be formed.

In some embodiments, for the magnetic force generator for the magnetized section MG5 to have a larger magnetic force, the coil in the magnetic force generator for the magnetized section MG5 may have a larger wire diameter than the magnetic force generators for the other magnetized sections, whereas the coils in all magnetic force generators have the same number of turns.

As described in detail above, the rotation angle detector 10 according to the first embodiment includes the ring magnet 20A that rotates together with the hollow shaft 16 and includes the magnetized sections MG1 to MG12 having different poles and being alternately arranged in the direction of rotation of the hollow shaft 16, and the MR sensor 15a that detects the magnetic fluxes of the magnetized sections MG1 to MG12. The magnetized sections MG1 to MG12 include the origin-indicator magnetized section 21 that generates a magnetic flux indicating completion of one rotation of the hollow shaft 16.

The controller CT electrically connected to the rotation angle detector 10 can thus detect both the rotation angle of the hollow shaft 16 and the origin using the single ring magnet 20A and the single MR sensor 15a. The rotation angle detector 10 is thus smaller and less expensive and can improve detection accuracy.

In addition, the magnetic force MP1 of the origin-indicator magnetized section 21 (magnetized section MG5) is larger than the magnetic forces MP2 of the other magnetized sections MG1 to MG4 and MG6 to MG12 included in the multiple magnetized sections MG1 to MG12 (MP1>MP2).

Thus, the ring magnet 20A can be magnetized using a known magnetizer with minor modifications. This structure can avoid increasing the manufacturing cost.

### Second Embodiment

A second embodiment will now be described in detail with reference to the drawings. Like reference numerals denote like functional elements in the above first embodiment. Such elements will not be described.

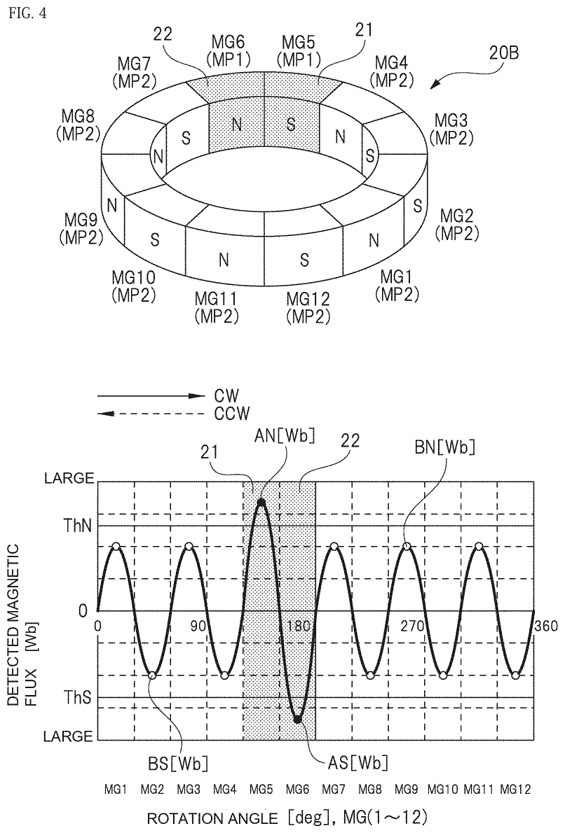

FIG. 4 shows a ring magnet in the second embodiment and a magnetic flux detected with the ring magnet.

As shown in FIG. 4, a ring magnet 20B in the second embodiment includes a magnetized section MG6 (shaded part in the figure) adjacent to a magnetized section MG5 (origin-indicator magnetized section 21), of 12 magnetized sections MG1 to MG12, serving as an origin-indicator magnetized section 22 (strongly magnetized section), unlike the ring magnet 20A in the first embodiment (refer to FIG. 3).

In other words, in the second embodiment, the pair of adjacent magnetized sections MG5 and MG6 (shaded part in the figure) with different poles, of the multiple (12) magnetized sections MG1 to MG12, serve as the origin-indicator magnetized sections 21 and 22.

In this structure, the MR sensor 15a (refer to FIG. 1) facing the ring magnet 20B outputs a sinusoidal detection signal (detected magnetic flux in Wb) as shown in the lower graph in FIG. 4. More specifically, the MR sensor 15a detects a larger magnetic flux when facing the origin-indicator magnetized section 21 or 22 (magnetized section MG5 or MG6) than when facing any one of the other N- and S-polar magnetized sections MG1 to MG4 and MG7 to MG12, as shown in the shaded area in the graph. In the figure, the magnetic flux levels AN and AS (Wb) detected at the black-dotted peaks (marked with black dots at two points) each are about 1.5 times larger than the magnetic flux level BN or BS (Wb) detected at the other white-dotted peaks (marked with white dots at ten points) (AN≈1.5×BN and AS≈1.5×BS). Specifically, when the magnetic flux levels AN and AS (Wb) detected at the points marked with black dots represent a ripple of 100%, the magnetic flux levels BN and BS (Wb) detected at the points marked with white dots represent a ripple of about 90% (a ripple difference is about 10%).

Thus, the controller CT detecting any one of the two outstanding peak points (marked with black dots) can detect the completion of one rotation of the hollow shaft 16 (the origin or reference point of rotation of the hollow shaft 16).

When the detected magnetic flux level AS (Wb) is used, the controller CT compares the detected magnetic flux level AS (Wb) as the major peak value (marked with a black dot) and the detected magnetic flux level BS (Wb) as the minor peak value (marked with a white dot) with a predetermined comparison threshold ThS (Wb) stored in, for example, a RAM (not shown) in the controller CT (AS>ThS>BS). The controller CT thus detects the single major S-polar peak value (marked with a black dot) between 0 and 360 degrees and determines that the detected peak indicates the origin of the hollow shaft 16.

The above structure in the second embodiment also produces the same advantageous effects as in the above first embodiment. In addition to this, the structure in the second embodiment can also detect the direction of rotation of the hollow shaft 16.

More specifically, the controller CT detects the magnetic flux level AN (Wb) and the magnetic flux level AS (Wb), which are the major peak values (marked with black dots). The controller CT first detecting the magnetic flux level AN (Wb) as the major peak value (marked with a black dot) and subsequently detecting the magnetic flux level AS (Wb) as the major peak value (marked with a black dot) can determine that the direction of rotation of the hollow shaft 16 is clockwise (CW). In contrast, the controller CT first detecting the magnetic flux level AS (Wb) as the major peak value (marked with a black dot) and subsequently detecting the magnetic flux level AN (Wb) as the major peak value (marked with a black dot) can determine that the direction of rotation of the hollow shaft 16 is counterclockwise (CCW).

### Third Embodiment

A third embodiment will now be described in detail with reference to the drawings. Like reference numerals denote like functional elements in the above first embodiment. Such elements will not be described.

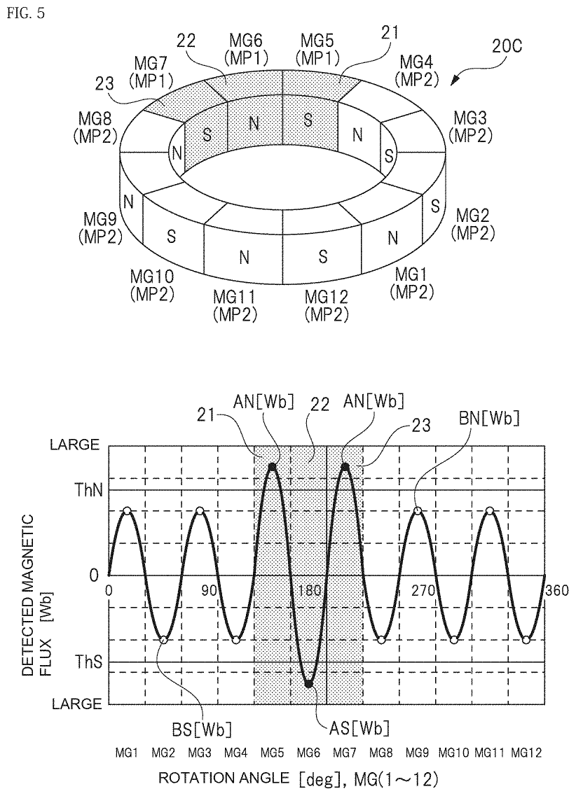

FIG. 5 shows a ring magnet in the third embodiment and a magnetic flux detected with the ring magnet.

As shown in FIG. 5, a ring magnet 20C in the third embodiment includes magnetized sections MG6 and MG7 (shaded part in the figure) adjacent to a magnetized section MG5 (origin-indicator magnetized section 21), of 12 magnetized sections MG1 to MG12, serving as origin-indicator magnetized sections 22 and 23 (strongly magnetized sections), unlike the ring magnet 20A in the first embodiment (refer to FIG. 3).

In this structure, the MR sensor 15a (refer to FIG. 1) facing the ring magnet 20C outputs a sinusoidal detection signal (detected magnetic flux in Wb) as shown in the lower graph in FIG. 5. More specifically, the MR sensor 15a detects a larger magnetic flux when facing the origin-indicator magnetized section 21, 22, or 23 (magnetized section MG5, MG6, or MG7) than when facing any one of the other N- and S-polar magnetized sections MG1 to MG4 and MG8 to MG12, as shown in the shaded area in the graph. In the figure, each of the magnetic flux levels detected at the black-dotted peaks (AN in Wb marked with black dots at two points and AS in Wb marked with a black dot at one point) is about 1.5 times larger than the magnetic flux levels detected at the other white-dotted peaks (BN or BS in Wb marked with white dots at nine points) (AN≈1.5×BN, AS≈1.5×BS). Specifically, when the magnetic flux levels AN and AS (Wb) detected at the points marked with black dots represent a ripple of 100%, the magnetic flux levels BN and BS (Wb) detected at the points marked with white dots represent a ripple of about 90% (a ripple difference is about 10%).

In this case, the controller CT detecting the magnetic flux level AS (Wb) at the one point can detect the completion of one rotation of the hollow shaft 16 (the origin or reference point of rotation of the hollow shaft 16). More specifically, the controller CT compares the detected magnetic flux level AS (Wb) as the major peak value (marked with a black dot) and the detected magnetic flux level BS (Wb) as the minor peak value (marked with a white dot) with the predetermined comparison threshold ThS (Wb) stored in, for example, a RAM (not shown) in the controller CT (AS>ThS>BS). The controller CT thus detects the single major S-polar peak value (marked with a black dot) between 0 and 360 degrees and determines that the detected peak indicates the origin of the hollow shaft 16.

The above structure in the third embodiment also produces the same advantageous effects as in the above first embodiment. In the third embodiment, in addition to this, the magnetized sections MG5 and MG7 adjacent to the origin-indicator magnetized section 22 (magnetized section MG6) also serve as the origin-indicator magnetized sections 21 and 23 (strongly magnetized sections). Thus, the controller CT determines that the hollow shaft 16 is in the range of rotation angles from 120 to 210 degrees by continuously detecting that the magnetic flux level AN (Wb) at the major peak value (marked with a black dot) exceeds the comparison threshold ThN (Wb), then the magnetic flux level AS (Wb) at the major peak value (marked with a black dot) exceeds the comparison threshold ThS (Wb), and finally the magnetic flux level AN (Wb) at the major peak value (marked with a black dot) exceeds the comparison threshold ThN (Wb). As in the second embodiment, the controller CT can also detect the direction of rotation of the hollow shaft 16. The controller CT can further predict the origin (magnetic flux level AS (Wb) at a major peak value) by detecting one of the magnetic flux levels AN (Wb) at the major peak value.

### Fourth and Fifth Embodiments

Fourth and fifth embodiments will now be described in detail with reference to the drawings. Like reference numerals denote like functional elements in the above first embodiment. Such elements will not be described.

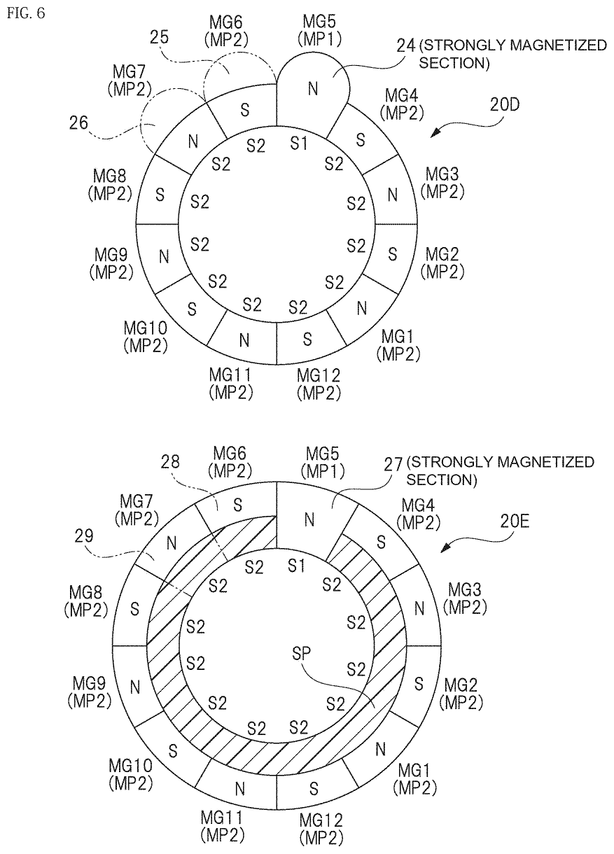

FIG. 6 shows ring magnets in the fourth and fifth embodiments.

As shown in FIG. 6, a ring magnet 20D in the fourth embodiment and a ring magnet 20E in the fifth embodiment each include a magnetized section MG5 (origin-indicator magnetized section 24 or 27), of 12 magnetized sections MG1 to MG12, with a shape different from the shape of each of the other magnetized sections MG1 to MG4 and MG6 to MG12, unlike the ring magnet 20A in the first embodiment (refer to FIG. 3). The symbols N and S in FIG. 6 indicate the polarity at the radially outer ends of the ring magnets 20D and 20E.

More specifically, in the ring magnet 20D (outward protrusion type) in the fourth embodiment, the origin-indicator magnetized section 24 (magnetized section MG5) protrudes radially outward from the ring magnet 20D, and has a volume S1 larger than a volume S2 of each of the other magnetized sections MG1 to MG4 and MG6 to MG12 (S1>S2). Thus, magnetizing the ring magnet 20D using a magnetizer causes the magnetic force MP1 of the magnetized section MG5 to be larger than the magnetic forces MP2 of the other magnetized sections MG1 to MG4 and MG6 to MG12.

The magnetizer for magnetizing the ring magnet 20D (outward protrusion type) includes a total of 12 magnetic force generators each corresponding to one of the magnetized sections MG1 to MG12 in the ring magnet 20D. The coils in these magnetic force generators each have the same number of turns (turns). This allows the use of a general-purpose magnetizer with a simple structure.

To obtain the same characteristics as those in the second and third embodiments above, the magnetized sections MG6 and MG7 may also protrude radially outward to serve as the origin-indicator magnetized sections 25 and 26 (strongly magnetized sections), as indicated by the two-dot-dash lines in the figure.

In the ring magnet 20E (inward protrusion type) in the fifth embodiment, the origin-indicator magnetized section 27 (magnetized section MG5) protrudes radially inward from the ring magnet 20E, and has a volume S1 larger than a volume S2 of each of the other magnetized sections MG1 to MG4 and MG6 to MG12 (S1>S2). Thus, magnetizing the ring magnet 20E using a magnetizer causes the magnetic force MP1 of the magnetized section MG5 to be larger than the magnetic forces MP2 of the other magnetized sections MG1 to MG4 and MG6 to MG12.

As a magnetizer for magnetizing the ring magnet 20E (inner protrusion type) as well, a general-purpose magnetizer with a simple structure may be used as for the ring magnet 20D in the fourth embodiment. A resin (non-magnetic) spacer SP is attached to the radially inner end of the ring magnet 20E. Thus, the ring magnet 20E is fixed to the hollow shaft 16 (refer to FIG. 1) without rattling.

To obtain the same characteristics as those in the first to third embodiments above, the magnetized sections MG6 and MG7 may also protrude radially inward to serve as the origin-indicator magnetized sections 28 and 29 (strongly magnetized sections), as indicated by the two-dot-dash lines in the figure.

The above structures in the fourth and fifth embodiments also produce substantially the same advantageous effects as in the above first embodiment.

### Sixth Embodiment

A sixth embodiment will now be described in detail with reference to the drawings. Like reference numerals denote like functional elements in the above first embodiment. Such elements will not be described.

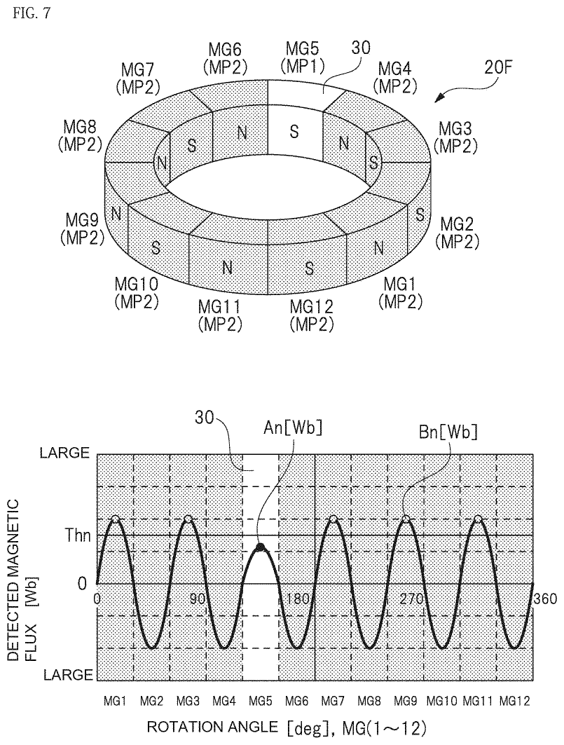

FIG. 7 shows a ring magnet in the sixth embodiment and a magnetic flux detected with the ring magnet.

As shown in FIG. 7, a ring magnet 20F in the sixth embodiment includes a magnetized section MG5 (outlined area in the figure), of 12 magnetized sections MG1 to MG12, serving as an origin-indicator magnetized section 30 (weakly magnetized section), unlike the ring magnet 20A in the first embodiment (refer to FIG. 3). In other words, in the sixth embodiment, the magnitudes of the magnetic forces are in a relationship opposite to the relationship in the first embodiment.

The origin-indicator magnetized section 30 (magnetized section MG5) generates a (small) magnetic flux indicating that the hollow shaft 16 has completed one rotation. More specifically, the origin-indicator magnetized section 30 has a magnetic force different from the magnetic force of each of the other magnetized sections MG1 to MG4 and MG6 to MG12, which is smaller than the magnetic forces of the other magnetized sections MG1 to MG4 and MG6 to MG12. In other words, the magnetic force MP1 of the magnetized section MG5 is smaller than the magnetic forces MP2 of the other magnetized sections MG1 to MG4 and MG6 to MG12 (MP1<MP2). The magnetized sections MG1 to MG12 including the origin-indicator magnetized section 30 (magnetized section MG5) each have the same volume.

In this structure, the MR sensor 15a (refer to FIG. 1) facing the ring magnet 20F outputs a sinusoidal detection signal (detected magnetic flux in Wb) as shown in the lower graph in FIG. 7. More specifically, the MR sensor 15a detects a smaller magnetic flux when facing the origin-indicator magnetized section 30 (magnetized section MG5) than when facing any one of the other N-polar magnetized sections MG1, MG3, MG7, MG9, and MG11, as shown in the outlined area in the graph. In the figure, the magnetic flux level An (Wb) detected at the black-dotted peak (marked with a black dot at one point) is about a half (½) of the magnetic flux level Bn (Wb) detected at the other white-dotted peaks (marked with white dots at five points) (An≈0.5×Bn). Specifically, when the magnetic flux level Bn (Wb) at the points marked with white dots represents a ripple of 100%, the magnetic flux level An (Wb) detected at the point marked with a black dot represents a ripple of about 90% (a ripple difference is about 10%).

Thus, the controller CT detecting the one peak point (marked with a black dot) that is smaller can detect the completion of one rotation of the hollow shaft 16 (the origin or reference point of rotation of the hollow shaft 16). More specifically, the controller CT compares the detected magnetic flux level An (Wb) as the minor peak value (marked with a black dot) and the detected magnetic flux level Bn (Wb) as the major peak value (marked with a white dot) with a predetermined comparison threshold Thn (Wb) stored in, for example, a RAM (not shown) in the controller CT (An<Thn<Bn). The controller CT thus detects the single minor N-polar peak value (marked with a black dot) between 0 and 360 degrees and determines that the detected peak indicates the origin of the hollow shaft 16.

The single minor peak value between 0 and 360 degrees may be an S-polar peak instead of an N-polar peak. The controller CT can detect the origin of the hollow shaft 16 as well. The magnetic forces of the magnetized sections MG1 to MG12 decrease based on thermal history. Thus, the controller CT may adjust the comparison threshold Thn based on thermal history.

The above structure in the sixth embodiment also produces substantially the same advantageous effects as in the above first embodiment. However, in a magnetizer used for magnetizing the ring magnet 20F in the sixth embodiment, the coil of the magnetic force generator for the magnetized section MG5 has a smaller number of turns than the coils of the magnetic force generators for the other magnetized sections MG1 to MG4 and MG6 to MG12, in a manner opposite to the first embodiment. Any structure may be used when the magnetic force generated by the magnetic force generator for the magnetized section MG5 is smaller than the other sections. The magnetic force generator may have no coil wound for the magnetized section MG5. In this case, the magnetized section MG5 is weakly magnetized by leakage flux from the magnetic force generators for the magnetized sections MG4 and MG6.

### Seventh Embodiment

A seventh embodiment will now be described in detail with reference to the drawings. Like reference numerals denote like functional elements in the above sixth embodiment. Such elements will not be described.

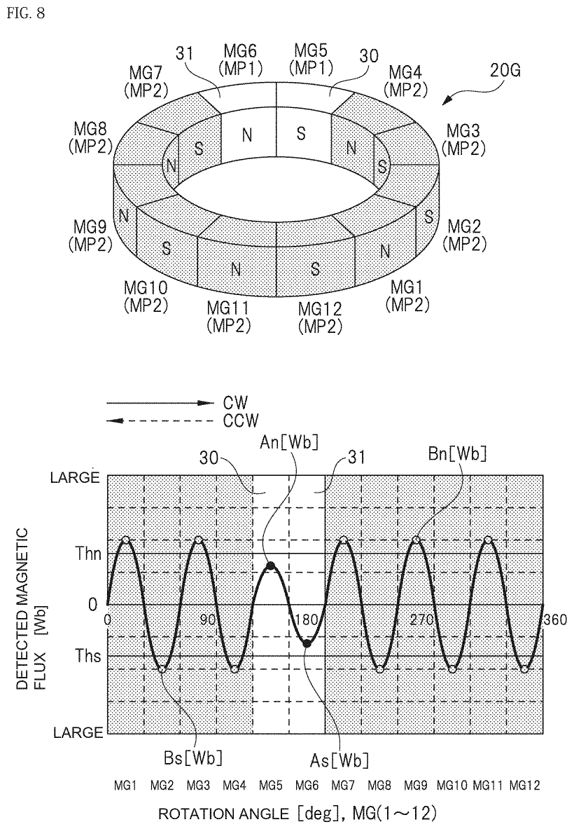

FIG. 8 shows a ring magnet in the seventh embodiment and a magnetic flux detected with the ring magnet.

As shown in FIG. 8, a ring magnet 20G in the seventh embodiment includes a magnetized section MG6 (outlined area in the figure) adjacent to a magnetized section MG5 (origin-indicator magnetized section 30), of 12 magnetized sections MG1 to MG12, serving as an origin-indicator magnetized section 31 (weakly magnetized section), unlike the ring magnet 20F in the sixth embodiment (refer to FIG. 7).

In other words, in the seventh embodiment, a pair of adjacent magnetized sections MG5 and MG6 with different poles, of the multiple (12) magnetized sections MG1 to MG12, serve as the origin-indicator magnetized sections 30 and 31.

In this structure, the MR sensor 15a (refer to FIG. 1) facing the ring magnet 20G outputs a sinusoidal detection signal (detected magnetic flux in Wb) as shown in the lower graph in FIG. 8. More specifically, the MR sensor 15a detects a smaller magnetic flux when facing the origin-indicator magnetized section 30 or 31 (magnetized section MG5 or MG6) than when facing any one of the other N- and S-polar magnetized sections MG1 to MG4 and MG7 to MG12, as shown in the outlined area in the graph. In the figure, the magnetic flux levels An and As (Wb) detected at the black-dotted peaks (marked with black dots at two points) each are about a half (½) of the magnetic flux level Bn or Bs (Wb) detected at the other white-dotted peaks (marked with white dots at ten points) (An≈0.5×Bn, As≈0.5×Bs). Specifically, when the magnetic flux levels Bn and Bs (Wb) at the points marked with white dots represent a ripple of 100%, the magnetic flux levels An and As (Wb) detected at the points marked with black dots represent a ripple of about 90% (a ripple difference is about 10%).

Thus, the controller CT detecting any one of the two minor peak points marked with black dots can detect the completion of one rotation of the hollow shaft 16 (the origin or reference point of rotation of the hollow shaft 16).

When the detected magnetic flux level As (Wb) is used, the controller CT compares the detected magnetic flux level As (Wb) as the minor peak value (marked with a black dot) and the detected magnetic flux level Bs (Wb) as the major peak value (marked with a white dot) with the predetermined comparison threshold Ths (Wb) stored in, for example, a RAM (not shown) in the controller CT (As<Ths<Bs). The controller CT thus detects the single minor S-polar peak value (marked with a black dot) between 0 and 360 degrees and determines that the detected peak indicates the origin of the hollow shaft 16.

The above structure in the seventh embodiment also produces substantially the same advantageous effects as in the above sixth embodiment. In addition to this, the structure in the seventh embodiment can also detect the direction of rotation of the hollow shaft 16.

More specifically, the controller CT detects the magnetic flux level An (Wb) and the magnetic flux level As (Wb), which are the minor peak values (marked with black dots). The controller CT first detecting the magnetic flux level An (Wb) as the minor peak value (marked with a black dot) and subsequently detecting the magnetic flux level As (Wb) as the minor peak value (marked with a black dot) can determine that the direction of rotation of the hollow shaft 16 is clockwise (CW). In contrast, the controller CT first detecting the magnetic flux level As (Wb) as the minor peak value (marked with a black dot) and subsequently detecting the magnetic flux level An (Wb) as the minor peak value (marked with a black dot) can determine that the direction of rotation of the hollow shaft 16 is counterclockwise (CCW).

### Eighth Embodiment

An eighth embodiment will now be described in detail with reference to the drawings. Like reference numerals denote like functional elements in the above sixth embodiment. Such elements will not be described.

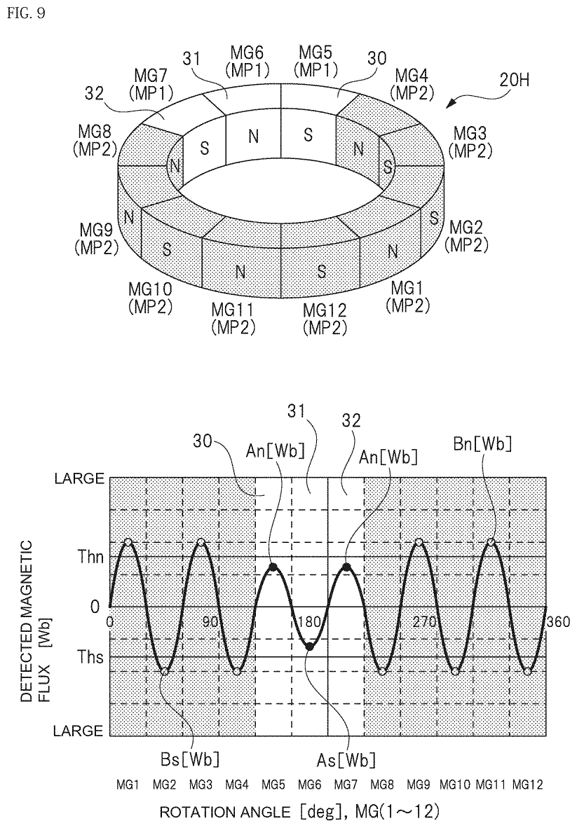

FIG. 9 shows a ring magnet in the eighth embodiment and a magnetic flux detected with the ring magnet.

As shown in FIG. 9, a ring magnet 20H in the eighth embodiment includes magnetized sections MG6 and MG7 (outlined area in the figure) adjacent to a magnetized section MG5 (origin-indicator magnetized section 30), of 12 magnetized sections MG1 to MG12, serving as origin-indicator magnetized sections 31 and 32 (weakly magnetized sections), unlike the ring magnet 20F in the sixth embodiment (refer to FIG. 7).

In this structure, the MR sensor 15a (refer to FIG. 1) facing the ring magnet 20H outputs a sinusoidal detection signal (detected magnetic flux in Wb) as shown in the lower graph in FIG. 9. More specifically, the MR sensor 15a detects a smaller magnetic flux when facing the origin-indicator magnetized section 30, 31, or 32 (magnetized section MG5, MG6, or MG7) than when facing any one of the other N- and S-polar magnetized sections MG1 to MG4 and MG8 to MG12, as shown in the outlined area in the graph. In the figure, the magnetic flux levels detected at the black-dotted peaks (An in Wb marked with black dots at two points and As in Wb marked with a black dot at one point) each are about a half (½) of the magnetic flux levels detected at the other white-dotted peaks (Bn or Bs in Wb with white dots at nine points) (An≈0.5×Bn, As≈0.5×Bs). Specifically, when the magnetic flux levels Bn and Bs (Wb) at the points marked with white dots represent a ripple of 100%, the magnetic flux levels An and As (Wb) detected at the points marked with black dots represent a ripple of about 90% (a ripple difference is about 10%).

In this case, the controller CT detecting the magnetic flux level As (Wb) at the one point can detect the completion of one rotation of the hollow shaft 16 (the origin or reference point of rotation of the hollow shaft 16). More specifically, the controller CT compares the detected magnetic flux level As (Wb) as the minor peak value (marked with a black dot) and the detected magnetic flux level Bs (Wb) as the major peak value (marked with a white dot) with the predetermined comparison threshold Ths (Wb) stored in, for example, a RAM (not shown) in the controller CT (As<Ths<Bs). The controller CT thus detects the single minor S-polar peak value (marked with a black dot) between 0 and 360 degrees and determines that the detected peak indicates the origin of the hollow shaft 16.

The above structure in the eighth embodiment also produces substantially the same advantageous effects as in the above sixth embodiment. In the eighth embodiment, in addition to this, the magnetized sections MG5 and MG7 adjacent to the origin-indicator magnetized section 31 (magnetized section MG6) also serve as the origin-indicator magnetized sections 30 and 32 (weakly magnetized sections). Thus, the controller CT determines that the hollow shaft 16 is in the range of rotation angles from 120 to 210 degrees by continuously detecting the magnetic flux level An (Wb) at the minor peak value (marked with a black dot) (without exceeding the comparison threshold Thn in Wb), and then the magnetic flux level As (Wb) at the minor peak value (marked with a black dot) (without exceeding the comparison threshold Thn in Wb), and finally the magnetic flux level An (Wb) at the minor peak value (marked with a black dot) (without exceeding the comparison threshold Thn in Wb). As in the seventh embodiment, the controller CT can also detect the direction of rotation of the hollow shaft 16. The controller CT can further predict the origin (magnetic flux level As (Wb) at a minor peak value) by detecting one of the magnetic flux levels An (Wb) at the minor peak value.

### Ninth and Tenth Embodiments

Ninth and tenth embodiments will now be described in detail with reference to the drawings. Like reference numerals denote like functional elements in the above sixth embodiment. Such elements will not be described.

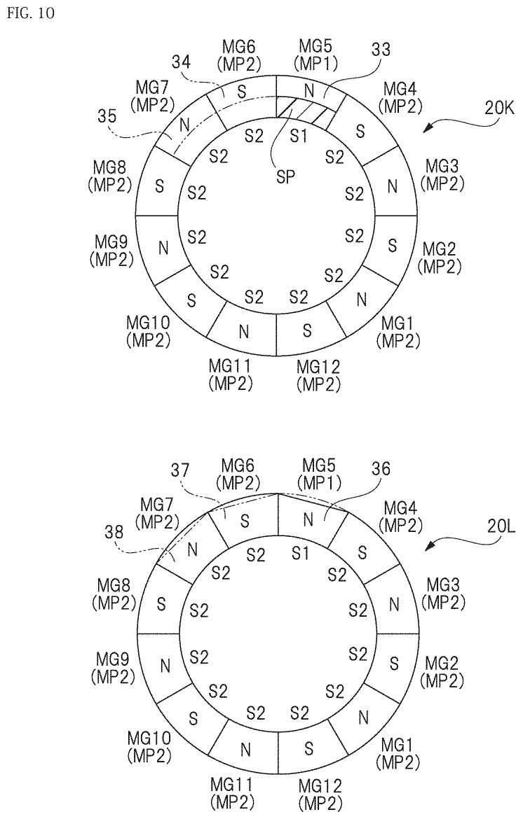

FIG. 10 is a schematic view of ring magnets in the ninth and tenth embodiments.

As shown in FIG. 10, a ring magnet 20K in the ninth embodiment and a ring magnet 20L in the tenth embodiment each include a magnetized section MG5 (origin-indicator magnetized section 33 or 36), of 12 magnetized sections MG1 to MG12, with a shape different from the shape of each of the other magnetized sections MG1 to MG4 and MG6 to MG12, unlike the ring magnet 20F in the sixth embodiment (refer to FIG. 7). The symbols N and S in FIG. 10 indicate the polarity at the radially outer end of the ring magnets 20K and 20L.

More specifically, in the ring magnet 20K (inner recess type) in the ninth embodiment, the origin-indicator magnetized section 33 (magnetized section MG5) is recessed radially outward into the ring magnet 20K, and has a volume S1 smaller than a volume S2 of each of the other magnetized sections MG1 to MG4 and MG6 to MG12 (S1<S2). Thus, magnetizing the ring magnet 20K using a magnetizer causes the magnetic force MP1 of the origin-indicator magnetized section MG5 to be smaller than the magnetic forces MP2 of the other magnetized sections MG1 to MG4 and MG6 to MG12.

The magnetizer for magnetizing the ring magnet 20K (inner recess type) includes a total of 12 magnetic force generators each corresponding to one of the magnetized sections MG1 to MG12 in the ring magnet 20K. The coils in these magnetic force generators each have the same number of turns (turns). This allows the use of a general-purpose magnetizer with a simple structure.

To obtain the same characteristics as those of the seventh and eighth embodiments above, magnetized sections MG6 and MG7 may also be recessed radially outward to serve as the origin-indicator magnetized sections 34 and 35 (weakly magnetized sections), as indicated by the two-dot-dash lines in the figure.

A resin (non-magnetic) spacer SP is attached to the radially inner end of the origin-indicator magnetized section 33. Thus, the ring magnet 20K is fixed to the hollow shaft 16 (refer to FIG. 1) without rattling.

In the ring magnet 20L (outer cut type) in the tenth embodiment, an outer peripheral portion of the origin-indicator magnetized section 36 (magnetized section MG5) is cut by a predetermined volume (shown by the two-dot-dash line in the figure) into a flat surface. Thus, the origin-indicator magnetized section 36 (magnetized section MG5) has a volume S1 smaller than a volume S2 of any one of the other magnetized sections MG1 to MG4 and MG6 to MG12 (S1<S2). Thus, magnetizing the ring magnet 20L using a magnetizer causes the magnetic force MP1 of the origin-indicator magnetized section MG5 to be smaller than the magnetic forces MP2 of the other magnetized sections MG1 to MG4 and MG6 to MG12.

As a magnetizer for magnetizing the ring magnet 20L (outer cut type) as well, a general-purpose magnetizer with a simple structure may be used as for the ring magnet 20K in the ninth embodiment.

To obtain the same characteristics as those of the seventh and eighth embodiments above, outer peripheral portions of the magnetized sections MG6 and MG7 may also be cut into flat surfaces to allow these magnetized sections to serve as the origin-indicator magnetized sections 37 and 38 (weakly magnetized sections), as indicated by the two-dot-dash lines in the figure.

The above structures in the ninth and tenth embodiments also produce substantially the same advantageous effects as in the sixth embodiment.

### Eleventh Embodiment

An eleventh embodiment will now be described in detail with reference to the drawings. Like reference numerals denote like functional elements in the above first embodiment. Such elements will not be described.

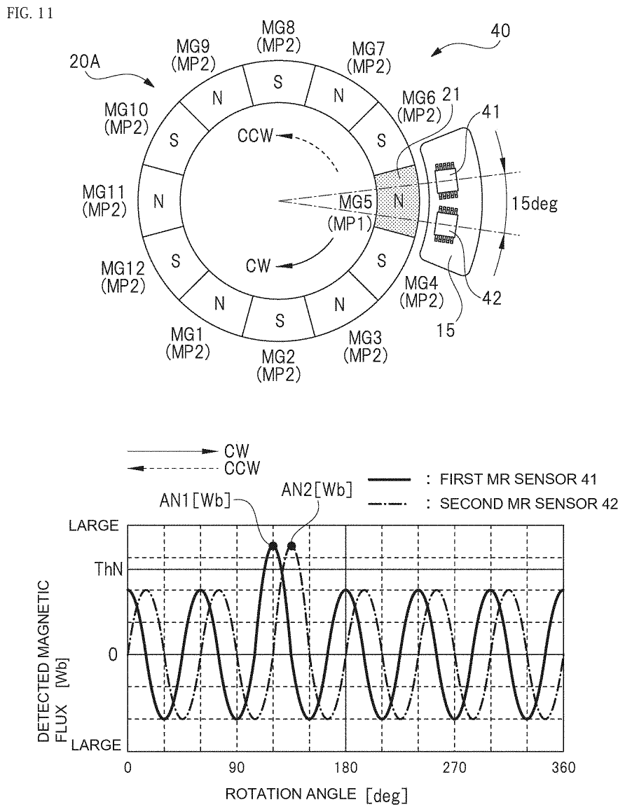

FIG. 11 shows a rotation angle detector according to the eleventh embodiment together and magnetic fluxes detected with the rotation angle detector.

As shown in FIG. 11, a rotation angle detector 40 according to the eleventh embodiment includes a first MR sensor 41 and a second MR sensor 42 mounted on a sensor board 15. The pair of first and second MR sensors 41 and 42 are magnetic sensors with the same structure and are displaced from each other by 15 degrees in the direction of rotation of the hollow shaft 16 (refer to FIG. 1).

In this structure, the first and second MR sensors 41 and 42 facing the ring magnet 20A each output a sinusoidal detection signal (detected magnetic flux in Wb) as shown in the lower graph in FIG. 11. In the graph, the solid line shows the detection signal from the first MR sensor 41, and the dotted line shows the detection signal from the second MR sensor 42.

More specifically, when facing an origin-indicator magnetized section 21 (magnetized section MG5) as the hollow shaft 16 rotates, the first and second MR sensors 41 and 42 output detection signals with a displacement of 15 degrees. In this case, the magnetic flux levels AN1 and AN2 (Wb) detected at the black-dotted larger peaks (marked with black dots at two points) are larger than the comparison threshold ThN (Wb). The controller CT (refer to FIG. 1) thus detects either one of the major N-polar peak values (marked with black dots) between 0 and 360 degrees and determines that the detected peak indicates the origin of the hollow shaft 16.

The pair of major peak values between 0 and 360 degrees may be S-polar peaks instead of N-polar peaks. As in the sixth embodiment described above, the magnetized section generating a magnetic flux that serves as an index (mark) (origin-indicator magnetized section) may be weakly magnetized. The controller CT can detect the origin of the hollow shaft 16 as well. The magnetic forces of magnetized sections MG1 to MG12 decrease based on thermal history. Thus, the controller CT may adjust the comparison threshold ThN based on thermal history.

The above structure in the eleventh embodiment also produces substantially the same advantageous effects as in the above first embodiment. In addition to this, the structure in the eleventh embodiment as well as the structure in the second embodiment can also detect the direction of rotation of the hollow shaft 16.

More specifically, the controller CT first detecting the magnetic flux level AN1 (Wb) as the major peak value (marked with a black dot) and subsequently detecting the magnetic flux level AN2 (Wb) as the major peak value (marked with a black dot) can determine that the direction of rotation of the hollow shaft 16 is clockwise (CW). In contrast, the controller CT first detecting the magnetic flux level AN2 (Wb) as the major peak value (marked with a black dot) and subsequently detecting the magnetic flux level AN1 (Wb) as the major peak value (marked with a black dot) can determine that the direction of rotation of the hollow shaft 16 is counterclockwise (CCW).

The present invention is not limited to the above embodiments, but may be modified variously without departing from the spirit and scope of the invention. For example, although each of the above embodiments is described using the 12-pole ring magnet 20A or 20L, the number of poles used in the embodiments of the present invention is not limited to this number and may be reduced to 8 or increased to 14 or more, for example, as appropriate for the specifications used for the rotation angle detector 10 or 40.

Although a magnetic sensor is used as an MR sensor in each of the above embodiments, the type of the sensor used in the embodiments of the present invention is not limited to this type of sensor and may be any other types of magnetic sensors, such as anisotropic magnetoresistive (AMR) sensors and giant magnetoresistive (GMR) sensors.

The materials, shapes, dimensions, numbers, and positions of the components in the above embodiments may be determined as appropriate to achieve the aspects of the present invention without being limited to the above embodiments.

What is claimed is:

1. A rotation angle detector for detecting a rotation angle of a rotator, the rotation angle detector comprising:
a magnet rotatable together with the rotator, the magnet including a plurality of magnetized sections having different poles and being alternately arranged in a direction of rotation of the rotator; and
a magnetic sensor configured to detect a magnetic flux of the plurality of magnetized sections,
wherein the plurality of magnetized sections include an origin-indicator magnetized section configured to generate a magnetic flux indicating completion of one rotation of the rotator.

2. The rotation angle detector according to claim 1, wherein
the origin-indicator magnetized section has a magnetic force different from magnetic forces of the other magnetized sections included in the plurality of magnetized sections.

3. The rotation angle detector according to claim 2, wherein
the magnetic force of the origin-indicator magnetized section is larger than the magnetic forces of the other magnetized sections included in the plurality of magnetized sections.

4. The rotation angle detector according to claim 3, wherein
the origin-indicator magnetized section has a volume larger than volumes of the other magnetized sections included in the plurality of magnetized sections.

5. The rotation angle detector according to claim 2, wherein
the magnetic force of the origin-indicator magnetized section is smaller than the magnetic forces of the other magnetized sections included in the plurality of magnetized sections.

6. The rotation angle detector according to claim 5, wherein
the origin-indicator magnetized section has a volume smaller than volumes of the other magnetized sections included in the plurality of magnetized sections.

7. The rotation angle detector according to claim 1, wherein
a pair of adjacent magnetized sections with different poles of the plurality of magnetized sections are each the origin-indicator magnetized section.

8. The rotation angle detector according to claim 1, wherein
the rotation angle detector comprises a pair of the magnetic sensors displaced in a direction of rotation of the rotator.
